(19) United States
(12) Patent Application Publication
(10) Pub. No.: US 2023/0207335 A1
(43) Pub. Date: Jun. 29, 2023

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Makoto Sambu, Toyama-shi (JP); Atsushi Hirano, Toyama-shi (JP); Yoshitaka Abe, Toyama-shi (JP)

(73) Assignee: Kokusai Electric Corporation, Tokyo (JP)

(21) Appl. No.: 18/172,785

(22) Filed: Feb. 22, 2023

Related U.S. Application Data
(63) Continuation of application No. PCT/JP2020/035872, filed on Sep. 23, 2020.

(51) Int. Cl. H01L 21/67; C23C 16/455; C23C 16/52; C23C 16/458

(52) U.S. Cl. CPC H01L 21/67017; C23C 16/45574; C23C 16/52; C23C 16/4583

(57) ABSTRACT

There is provided a technique that includes: a cylindrical outer tube; an inner tube that is installed inside the outer tube and configured such that a substrate is capable of being processed in a process chamber formed in the inner tube; a manifold that is installed below the outer tube and the inner tube, in fluid communication with an internal space of the inner tube, and formed in a cylindrical shape with an exhaust space isolated from an annular space between the inner tube and the outer tube; a process gas nozzle configured to supply a process gas that processes the substrate to an inside of the inner tube; a purge gas nozzle configured to supply a purge gas to the annular space; and a conductance changer that is installed at a partition wall between the annular space and the exhaust space.

### CROSS-REFERENCE TO RELATED APPLICATION

This application is a Bypass Continuation Application of PCT International Application No. PCT/JP2020/035872, filed Sep. 23, 2020, the disclosure of which is incorporated herein in its entirety by reference.

### TECHNICAL FIELD

The present disclosure relates to a substrate processing apparatus, a method of processing a substrate, a method of manufacturing a semiconductor device, and a recording medium.

### BACKGROUND

In a method of manufacturing a semiconductor integrated circuit device (hereinafter referred to as an IC (Integrated Circuit)), for example, a batch-type vertical hot-wall type CVD film-forming apparatus (hereinafter, referred to as a substrate processing apparatus) is used when forming a film of polycrystalline or monocrystalline silicon or silicon germanium on a silicon wafer. In the related art, as this type of substrate processing apparatus, there is a substrate processing apparatus that includes an outer tube and an inner tube arranged inside the outer tube, and performs a film formation on a silicon wafer by loading the silicon wafer into the inner tube, supplying a process gas into the inner tube while heating the inner tube with a heater.

However, in such a substrate processing apparatus, when the process gas flows into a space between the inner tube and the outer tube, a reaction product film (for example, a silicon or silicon germanium deposition film) may be formed on an inner surface of the outer tube facing the space, taking effort to remove the reaction product in the outer tube.

### SUMMARY

Some embodiments of the present disclosure provide a technique capable of suppressing formation of a reaction product film on an inner surface of an outer tube.

According to some embodiments of the present disclosure, there is provided a technique that includes a cylindrical outer tube with an upper end closed and a lower end opened; an inner tube that is installed inside the outer tube, formed in a cylindrical shape with an upper end closed and a lower end opened, and configured such that a substrate is capable of being processed in a process chamber formed in the inner tube; a manifold that is installed below the outer tube and the inner tube, in fluid communication with an internal space of the inner tube, and formed in a cylindrical shape with an exhaust space isolated from an annular space between the inner tube and the outer tube; a process gas nozzle configured to supply a process gas that processes the substrate to an inside of the inner tube; a purge gas nozzle configured to supply a purge gas to the annular space; and a conductance changer that is installed at a partition wall between the annular space and the exhaust space, configured such that a gas is capable of passing between the annular space and the exhaust space, and configured to be capable of changing a passage conductance of the gas.

### BRIEF DESCRIPTION OF DRAWINGS

The accompanying drawings, which are incorporated in and constitute a portion of the specification, illustrate embodiments of the present disclosure.

FIG. 1 is a longitudinal cross-sectional view showing a substrate processing apparatus according to embodiments of the present disclosure.

FIG. 2 is a horizontal cross-sectional view showing a substrate processing apparatus according to embodiments of the present disclosure.

FIG. 3 is a perspective view showing a conductance changer of a substrate processing apparatus according to embodiments of the present disclosure.

FIG. 4 is a perspective view showing a connection state between an inner tube fitting ring and an inner tube support.

FIG. 5 is a perspective view showing the vicinity of a lower end of an inner tube, showing a state where an inner tube is installed at an inward flange.

FIG. 6A is an axial cross-sectional view showing a vented set screw.

FIG. 6B is an axial cross-sectional view showing a normal set screw.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

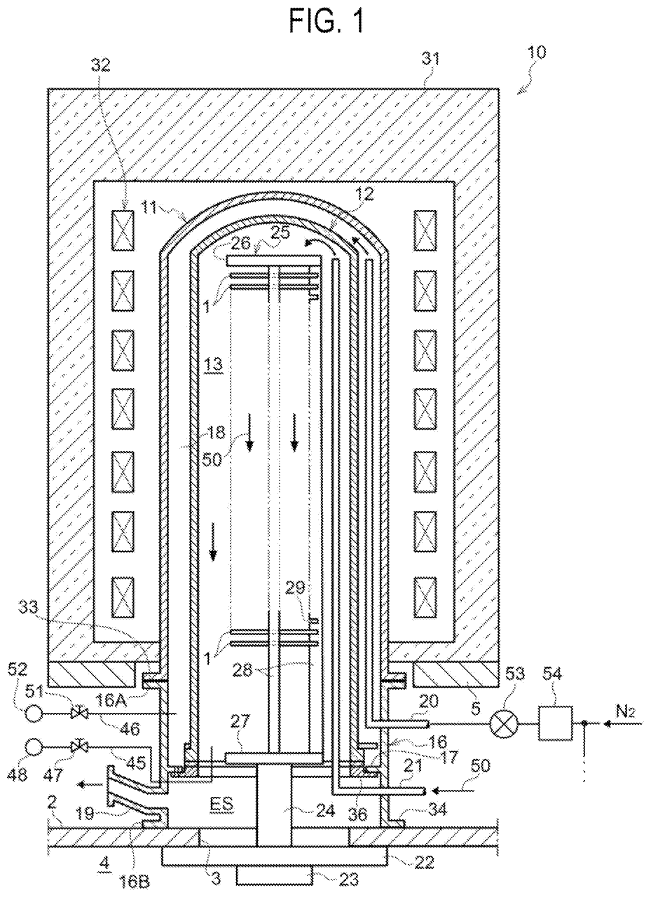

A substrate processing apparatus 10 according to embodiments of the present disclosure will now be described with reference to FIGS. 1 to 6B. The drawings used in the following description are schematic, and dimensional relationships, ratios, and the like among the respective components shown in figures may not match actual ones. Further, dimensional relationships, ratios, and the like of the respective components among plural figures do not always match each other.

A schematic structure of the substrate processing apparatus 10 according to the present disclosure is shown in a cross-sectional view in FIG. 1. The substrate processing apparatus 10 is used, for example, when manufacturing ICs and the like, and is constituted as a vertical CVD film-forming apparatus (batch-type vertical hot-wall type CVD film-forming apparatus) configured to deposit a polysilicon film on a silicon wafer (hereinafter, referred to as a substrate).

The substrate processing apparatus 10 shown in FIG. 1 includes a vertical outer tube 11 with a vertical central axis, and an inner tube 12 coaxially accommodated inside the outer tube 11. Further, an annular space 18 is formed between the outer tube 11 and the inner tube 12.

The outer tube 11 in the embodiments of the present disclosure is made of quartz and is formed in a cylindrical shape with its upper end closed. The inner tube 12 is made of silicon carbide (SiC) and is formed in a cylindrical shape with its upper end closed and a diameter smaller than that of the outer tube 11. The outer tube 11 is a pressure-resistant container and may be sealed with a seal material 33 as a first seal material described below. It is difficult for silicon carbide with a high thermal conductivity to be used for the outer tube 11 because it easily transfers heat in a furnace to the seal material 33 to expose the seal material 33 to a high temperature. The inner tube 12 may be formed to be thinner than the outer tube 11 and may not be strong to withstand a pressure difference between an atmospheric pressure and vacuum.

It is known that a coefficient of linear expansion of silicon carbide (SiC) is, for example, 4.2×10⁻⁶/K in a general product formed by a reaction sintering method in which 4H-SiC powder is used as a main precursor, a coefficient of linear expansion of a polycrystalline silicon film described below is 3.9×10⁻⁶/K, and the coefficient of linear expansion of silicon carbide (SiC) is +7.6% with respect to a coefficient of linear expansion of polycrystalline silicon. Incidentally, a coefficient of linear expansion of quartz (SiO₂) is 0.5×10⁻⁶/K.

An internal space of the inner tube 12 serves as a process chamber 13 into which a plurality of substrates 1 stacked by a boat 25 are loaded. Further, a lower end opening of the inner tube 12 constitutes a furnace opening 14 through which the boat 25 is taken in and out.

The outer tube 11 is fixed to an upper side of a short cylindrical manifold 16 installed at a housing 2 of the substrate processing apparatus 10.

The upper end of the manifold 16 is provided with an upper flange 16A protruding outward in the radial direction, the lower end of the manifold 16 is provided with a lower flange 16B protruding outward in the radial direction, and an inner periphery of the manifold 16 is provided with an inward flange (rib) 17 as a partition wall formed in a ring shape and protruding inward in the radial direction. In addition, the inward flange 17 is formed in an annular shape.

In the internal space of the manifold 16, a space between the inward flange 17 and the upper surface of the housing 2 serves as an exhaust space ES.

The lower end of the outer tube 11 is supported by the upper flange 16A of the manifold 16 via the seal material 33. The lower flange 16B of the manifold 16 is supported on the upper surface of the housing 2 via a seal material 34 as a second seal material.

An exhaust pipe 19 as an exhaust port, which is in fluid communication with the exhaust space ES, is installed at an outer wall of the manifold 16 below the inward flange 17. An exhauster (not shown) configured to exhaust a gas inside the exhaust space ES is connected to the exhaust pipe 19.

As shown in FIGS. 1 and 3 to 5, a flange (lip) 12A protruding outward in the radial direction is integrally formed at the lower end of the inner tube 12. The outer diameter of the flange 12A is smaller than the inner diameter of the inward flange 17, such that the flange 12A may pass through the inner side of the inward flange 17 of the manifold 16 in the axial direction (vertical direction).

A ring-shaped inner tube support 35 is arranged below the flange 12A, and a ring-shaped seal flange 36 as a mounter is arranged below the inner tube support 35. Further, a ring-shaped inner tube fitting ring 37 is arranged above the flange 12A.

The inner tube support 35 is ring-shaped and includes a plurality of protrusions 35A protruding outward in the radial direction and are formed on the outer periphery at intervals in the circumferential direction. The outer diameter of the inner tube support 35 excluding the protrusions 35A is smaller than the inner diameter of the inward flange 17.

Further, the inner tube fitting ring 37 is ring-shaped and includes protrusions 37A protruding outward in the radial direction and are formed on the outer periphery at positions facing the protrusions 35A of the inner tube support 35. The outer diameter of the inner tube fitting ring 37 excluding the protrusions 37A is smaller than the inner diameter of the inward flange 17.

A plurality of notches 17A are formed at the inner periphery of the inward flange 17 to allow the protrusions 35A of the inner tube support 35 and the protrusions 37A of the inner tube fitting ring 37 to pass through in the axial direction (vertical direction).

As a result, when the protrusions 37A of the inner tube fitting ring 37 and the protrusions 35A of the inner tube support 35 face the notches 17A of the inward flange 17, the inner tube fitting ring 37 and the inner tube support 35 may pass through the inward flange 17 in the axial direction (vertical direction).

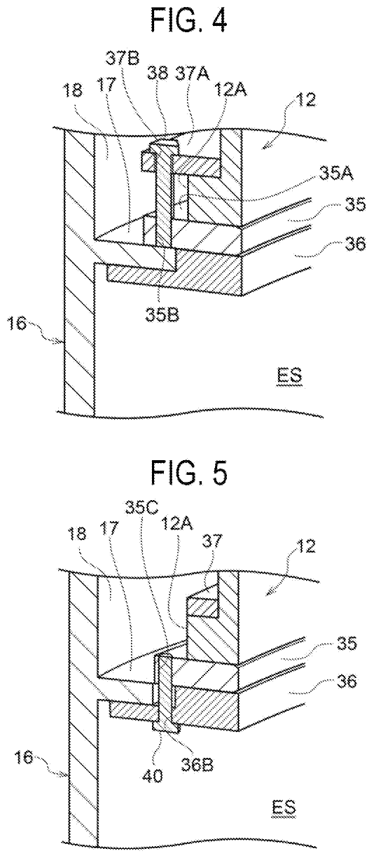

As shown in FIG. 4, the inner tube fitting ring 37 and the inner tube support 35 are connected to each other by a plurality of screws 38 in a state where the flange 12A of the inner tube 12 is interposed between the inner tube fitting ring 37 and the inner tube support 35. As a result, the inner tube fitting ring 37 and the inner tube support 35 are fixed to the flange 12A of the inner tube 12. Further, screw holes 35B into which the screws 38 are screwed are formed at the inner tube support 35, and holes 37B through which the screws 38 are inserted are formed at the inner tube fitting ring 37.

As shown in FIG. 5, the seal flange 36 is formed with a diameter larger than the inner diameter of the inward flange 17 and is in contact with the lower surface of the inward flange 17. The seal flange 36 is fixed to the inner tube support 35 by a plurality of screws 40, and the inner tube 12 is installed at the inward flange 17 by interposing the inward flange 17 between the inner tube support 35 and the seal flange 36. As a result, even in a case where a pressure of the process chamber 13 is higher than a pressure of the annular space 18, the inner tube 12 will not float or move. Further, screw holes 35C into which the screws 40 are screwed are formed at the inner tube support 35, and holes 36B through which the screws 40 are inserted are formed at the seal flange 36.

The outer diameter of each of the inner tube fitting ring 37, the inner tube 12, the inner tube support 35, and the seal flange 36 is smaller than the inner diameter of the manifold 16.

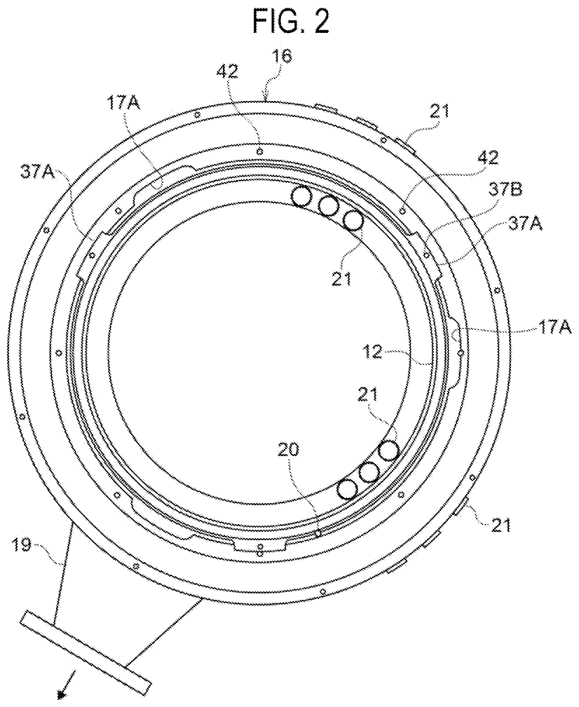

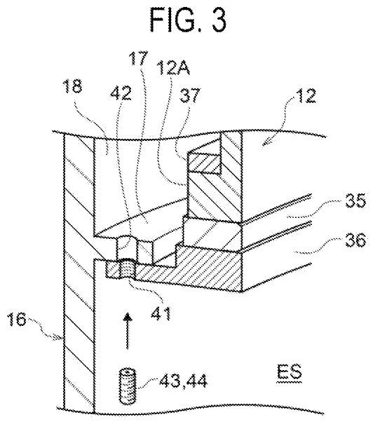

As shown in FIG. 3, a plurality of screw holes 41 (eight screw holes 41 in the embodiments of the present disclosure) are formed at the seal flange 36 at intervals in the circumferential direction, and a plurality of through-holes 42 (eight through-holes 42 in the embodiments of the present disclosure, see FIG. 2) are formed at the inward flange 17 at the same intervals as the screw holes 41.

Further, by rotating the inner tube 12 after passing the inner tube 12, the inner tube fitting ring 37, and the inner tube support 35 upward through the inward flange 17 with the protrusions 37A of the inner tube fitting ring 37 and the protrusions 35A of the inner tube support 35 facing the notches 17A of the inward flange 17, the screw holes 41 of the seal flange 36 and the through-holes 42 of the inward flange 17 may face each other. Further, with the screw holes 41 and the through-holes 42 facing each other, the inner tube 12 is installed at the inward flange 17 as described above.

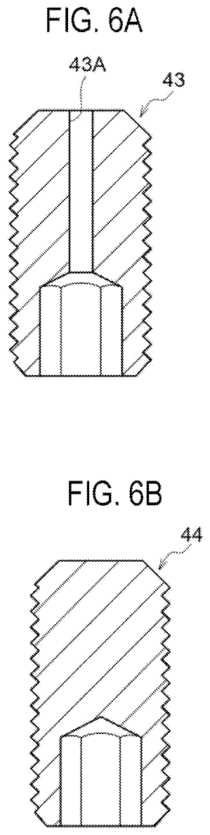

A vented set screw 43 with a hexagonal hole as shown in FIG. 6A or a normal set screw 44 with a hexagonal hole as shown in FIG. 6B may be screwed into the screw holes 41. A vent hole 43A with a diameter of, for example, 0.8 mm through which a gas may pass is formed at an axial center of the vented set screw 43.

The vented set screw 43 and the set screw 44 are, for example, M4 to M6 metric screws.

In the substrate processing apparatus 10, the vented set screw 43 is screwed into at least one selected from the group of the plurality of screw holes 41, and the set screw 44 or a normal screw is screwed into the remaining screw holes 41. As a result, the process chamber 13 and the annular space 18 are in fluid communication with the vent hole 43A of the vented set screw 43.

A conductance changer of the present disclosure includes the plurality of screw holes 41, the vented set screws 43, and the set screws 44. A conductance is the reciprocal of passage resistance of a gas when the gas flows from the annular space 18 to the exhaust space ES. For example, in a case where the number of vented set screws 43 is increased, the passage resistance is decreased and the conductance is increased.

### (Process Gas Nozzle)

As shown in FIGS. 1 and 2, a plurality of process gas nozzles 21 are inserted through a sidewall of the manifold 16 at positions lower than the inward flange 17, and opening ends of the process gas nozzles 21 are arranged at the upper end of the process chamber 13 or at the side of the substrate 1. In other words, each process gas nozzle 21 includes one opening at a tip of a pipe that is formed with the same shape and area as a cavity of the pipe. A large opening is not clogged with deposits, like a pinhole opening. The plurality of process gas nozzles 21 are different from one another in height inside the process chamber 13, and a flow rate of a precursor gas 50 discharged from each process gas nozzle 21 is controlled to ensure uniformity of film thickness and film quality (grain size) on the surface of each substrate 1. The process gas nozzle 21 may be made of the same material as the outer tube 11 or material different from that of the outer tube 11. Further, the process gas nozzle 21 is an example of a process gas nozzle of the present disclosure.

A gas supplier (not shown) is connected to the process gas nozzle 21, a process gas (the precursor gas 50, a hydrogen (H₂) gas as a pretreatment gas, or a nitrogen gas as a purge gas) is supplied from the gas supplier, and these gases are ejected into the process chamber 13 from the opening end of the process gas nozzle 21. The gas introduced into the process chamber 13 by the process gas nozzle 21 flows down the process chamber 13 and is exhausted to the outside via the exhaust space ES and the exhaust pipe 19.

### (Purge Gas Nozzle)

A purge gas nozzle 20 as a purge gas nozzle is inserted through the sidewall of the manifold 16, and the opening end of the purge gas nozzle 20 is arranged on the upper end side of the annular space 18. A gas supplier configured to supply a nitrogen gas as an inert gas is connected to the purge gas nozzle 20. The nitrogen gas introduced into the upper end of the annular space 18 by the purge gas nozzle 20 may flow down the annular space 18 and be exhausted from the vent hole 43A of the vented set screw 43 to the exhaust space ES.

The gas supplier is formed by connecting a control valve 53 and a flow rate controller 54 in series, and supplies a nitrogen gas from a nitrogen gas source to the purge gas nozzle 20 at a predetermined mass flow rate. Further, two pipes are connected to a pipe from the nitrogen gas source via a branch. One pipe is connected to the purge gas nozzle 20 via the gas supplier, and the other pipe is connected to the process gas nozzle 21 via a similar gas supplier (not shown).

As shown in FIG. 1, pipes 45 and 46 pass through the manifold 16. One end of the pipe 45 is arranged in the process chamber 13, and a first pressure gauge 48 is installed at the other end of the pipe 45 via an opening/closing valve 47. An internal pressure of the process chamber 13 may be detected by the first pressure gauge 48. The opening/closing valve 47 may be opened as appropriate, such as when the first pressure gauge 48 is used.

One end of the pipe 46 is arranged in the annular space 18, and a second pressure gauge 52 is installed at the other end of the pipe 46 via an opening/closing valve 51. An internal pressure of the annular space 18 may be detected by the second pressure gauge 52. Further, the opening/closing valve 51 may be opened as appropriate, such as when the second pressure gauge 52 is used.

A boat loading/unloading port 3 is opened at a location of the housing 2 facing the manifold 16. A seal cap 22 that is moved up or down by a boat elevator (not shown) is in contact with the lower surface of the housing 2 from below in the vertical direction so as to close the boat loading/unloading port 3.

The seal cap 22 is formed in a disc shape with an outer diameter larger than an inner diameter of the boat loading/unloading port 3, and a boat loading/unloading chamber 4 formed by the housing 2 below the outer tube 11 is moved up or down by the boat elevator.

A rotary shaft 24 that is rotated by a rotary actuator 23 is arranged on a central axis of the seal cap 22, and the boat 25 is vertically erected and supported on an upper end of the rotary shaft 24.

The boat 25 includes a pair of upper and lower end plates 26 and 27 and three holders 28 that are vertically arranged across the end plates 26 and 27. A large number of holding grooves 29 are formed at the three holders 28 at equal intervals in the longitudinal direction to open facing each other.

By inserting the substrates 1 among the holding grooves 29 of the three holders 28, the boat 25 aligns and holds the plurality of substrates 1 horizontally with centers of the substrates 1 aligned with one another. The boat 25 may be made of the same material as the outer tube 11 or material different from that of the outer tube 11.

The outside of the outer tube 11 is entirely covered with a heat insulating cover 31, and a heater 32 configured to heat the inside of the outer tube 11 is concentrically arranged inside the heat insulating cover 31 so as to surround the outer tube 11.

The heat insulating cover 31 and the heater 32 are vertically supported by a frame 5 built on the housing 2. The heater 32 is divided into a plurality of heaters, and these heaters are configured to be sequence-controlled in cooperation with each other and independently by a temperature controller (not shown).

### (Preliminary Provision)

First, preliminary provision (initial setting of the substrate processing apparatus 10) before the substrate 1 is processed by the substrate processing apparatus 10 of the embodiments of the present disclosure will be described. In this substrate processing apparatus 10, when the substrate 1 accommodated in the inner tube 12 is processed with the precursor gas 50, a nitrogen gas may be supplied to the annular space 18 to prevent the precursor gas 50 supplied to the inner tube 12 from flowing into the annular space 18. Further, an amount of nitrogen gas supplied to the annular space 18 may be controlled such that the nitrogen gas is not wasted.

Therefore, the number of installed vented set screws 43 is regulated, before actually processing the substrate 1, to make the pressure of the annular space 18 slightly higher than the internal pressure of the process chamber 13 and control the amount of nitrogen gas used (that is, the amount of nitrogen gas discharged from the annular space 18 to the exhaust space ES of the manifold 16).

In the preliminary provision, while the nitrogen gas is supplied from the process gas nozzle 21 into the process chamber 13, the inside of the process chamber 13 is exhausted by the exhauster such that the internal pressure of the process chamber 13 matches actual processing conditions. Further, the nitrogen gas is supplied to the annular space 18, the internal pressure of the process chamber 13 is detected by the first pressure gauge 48, and the internal pressure of the annular space 18 is detected by the second pressure gauge 52. Further, the substrate 1 may not be accommodated in the inner tube 12 in the preliminary provision.

Then, the number of vented set screws 43 is changed, and the internal pressure of the process chamber 13 and the internal pressure of the annular space 18 are detected and a flow rate of the nitrogen gas is checked. Then, a differential pressure between the internal pressure of the process chamber 13 and the internal pressure of the annular space 18 is kept constant such that the internal pressure of the annular space 18 is slightly higher than the internal pressure of the process chamber 13 or such that a gas flow velocity in the vent hole 43a is equal to or more than a predetermined value, and the number of vented set screws 43 is determined as appropriate in advance to control the amount of nitrogen gas used. Further, in a process in which the pressure of the process chamber 13 fluctuates greatly, the differential pressure may be kept at least below the withstand pressure of the inner tube. For example, when the differential pressure is kept low by allowing flow (including temporary backflow) through the vent holes 43a due to the pressure fluctuation, a minimum value of a total conductance of the vent holes 43a is determined based on a volume of the annular space 18 and a maximum pressure fluctuation rate. By completing this preliminary provision, the substrate 1 may be proceed actually. This preliminary provision may also be performed by desk calculation.

Further, in the substrate processing apparatus 10 in the embodiments of the present disclosure, the vented set screw 43 is screwed into the screw hole 41 located farthest from the purge gas nozzle 20, and the normal set screws 44 are screwed into the other screw holes 41.

### (Operations and Effects)

Next, operations and effects of the substrate processing apparatus 10 in which the preliminary provision is completed as described above will be described in regard to a case where a polycrystalline silicon film is formed on the substrate 1.

As shown in FIG. 1, the boat 25 aligning and holding the plurality of substrates 1 are placed on the seal cap 22 in a state in which a direction in which a group of substrates 1 is arranged is vertical. The group of substrates 1 is pushed up by the boat elevator, loaded into the process chamber 13 from the furnace opening 14 of the inner tube 12 (boat loading), and arranged in the process chamber 13 while being supported by the seal cap 22.

Subsequently, the air inside of the outer tube 11 is exhausted via the exhaust pipe 19 such that an internal pressure of the outer tube 11 becomes a predetermined pressure (for example, 0.1 to 100 Pa), and the inside of the outer tube 11 is heated by the heater 32 to a predetermined temperature (for example, a temperature around 650 degrees C. (500 to 750 degrees C.).

Next, a hydrogen (H₂) gas as a pretreatment gas is introduced into the upper end of the process chamber 13 by the process gas nozzle 21 at a predetermined flow rate (0.1 to 10 L/min). The hydrogen gas introduced into the upper end of the process chamber 13 by the process gas nozzle 21 flows down the process chamber 13 and is discharged to the outside of the substrate processing apparatus 10 via the exhaust space ES of the manifold 16 and the exhaust pipe 19. Then, the hydrogen gas contacts the substrates 1 held in the boat 25 while flowing down the process chamber 13, thereby performing the pretreatment such as reduction treatment on the substrates 1.

After a predetermined period of time elapses, for example, monosilane (SiH₄) and 0.1% diluted boron trichloride (BCl₃) are introduced, as the precursor gas 50 for silicon film formation, from the process gas nozzle 21 into the upper end of the process chamber 13.

A flow rate of the SiH₄ gas is, for example, 0.5 to 3 L/min, and a flow rate of the BCl₃ gas is 0.02 L/min or less. The precursor gas 50 introduced into the process chamber 13 by the process gas nozzle 21 flows down the process chamber 13 and is discharged to the outside of the substrate processing apparatus 10 via the exhaust space ES of the manifold 16 and the exhaust pipe 19.

Then, the precursor gas 50 contacts the substrates 1 held in the boat 25 while flowing down the process chamber 13 and causes a thermal CVD reaction, thus depositing polycrystalline silicon on the substrates 1 to form an epitaxial silicon film.

Further, when the precursor gas 50 is supplied into the process chamber 13, a nitrogen gas (N₂) is supplied from the purge gas nozzle 20 to the annular space 18 between the outer tube 11 and the inner tube 12.

Since the internal pressure of the annular space 18 is higher than an internal pressure of the inner tube 12 and an internal pressure of the exhaust space ES of the manifold 16 being in fluid communication with the inside of the inner tube 12, the nitrogen gas supplied to the annular space 18 is discharged to the exhaust space ES of the manifold 16 via the vent hole 43A of the vented set screw 43.

Further, since the temperature of the nitrogen gas is raised while flowing through the purge gas nozzle 20 and approaches the temperature of the process chamber 13 when it flows out from the opening end, unevenness in temperature or film thickness due to the nitrogen gas is suppressed. Further, since the nitrogen gas is discharged upward from the purge gas nozzle 20, circulates in the annular space 18 from the top to the bottom, and is discharged from the vent hole 43A of the vented set screw 43, stagnation of the nitrogen gas in the annular space 18 is suppressed.

Since the precursor gas 50 supplied to the inner tube 12 is suppressed from flowing and diffusing into the annular space 18 in this manner, a silicon film is suppressed from being deposited on the inner surface of the outer tube 11 facing the annular space 18 and the outer surface of the inner tube 12.

Further, the nitrogen gas discharged to the exhaust space ES of the manifold 16 is discharged to the outside of the substrate processing apparatus 10 together with the precursor gas 50 flowing down inside the inner tube 12 via the exhaust pipe 19.

After a predetermined film formation time elapses, the introduction of the precursor gas 50 is stopped, the nitrogen gas as the purge gas is introduced into the process chamber 13 from the process gas nozzle 21, and the precursor gas50 in the process chamber 13 and the exhaust space ES is exhausted to the outside via the exhaust pipe 19. After the precursor gas 50 is sufficiently exhausted, a passage from the exhaust pipe 19 to the exhauster is closed, and the inside of the process chamber 13 is returned to the atmospheric pressure. Further, the nitrogen gas may also be introduced into the process chamber 13 or the exhaust space ES from a diffusion nozzle (break-fill plate) (not shown) to expedite the return to the atmospheric pressure.

At this time, the nitrogen gas is also introduced into the annular space 18 between the outer tube 11 and the inner tube 12 by the purge gas nozzle 20, thereby keeping the differential pressure below a certain level. Further, the precursor gas 50 remaining in the inner tube 12 and the exhaust space ES of the manifold 16 is suppressed from flowing into and diffusing into the annular space 18.

When the process chamber 13 and the exhaust space ES are purged with the nitrogen gas and returned to the atmospheric pressure, the boat 25 supported by the seal cap 22 is lowered by the boat elevator and is unloaded from the furnace opening 14 of the inner tube 12 (boat unloading).

Thereafter, the substrate processing apparatus 10 performs batch processing of polycrystalline silicon film formation on the substrates 1 by repeating the above-described process. In the above-described process, polycrystalline silicon with a film thickness of 2 μm or more may be deposited on the substrates 1 at one time.

In the above-described film-forming process, since the precursor gas 50 contacts the inner surface of the inner tube 1 as well as the substrates 12 while flowing down the process chamber 13, epitaxial silicon is deposited on the inner surface of the inner tube 12 as well.

Since the coefficient of linear expansion of silicon carbide (SiC) forming the inner tube 12 and the coefficient of linear expansion of epitaxial silicon deposited on the inner surface of the inner tube 12 are close to each other, when the temperature of the inner tube 12 and the temperature of the epitaxial silicon deposited on the inner surface of the inner tube 12 change, a difference in expansion (change of dimension) between the inner tube 12 and the epitaxial silicon is small. Therefore, when the temperature changes (for example, when the substrates 1 are loaded, the substrates 1 are processed, or the substrates 1 are unloaded), a mechanical stress acting on the epitaxial silicon may be suppressed to be small, thereby suppressing a deposited film of epitaxial silicon accumulated on the inner surface of the inner tube 12 from peeling off. In this regard, these coefficients of linear expansion are defined as an average coefficient of linear expansion between the normal temperature and the processing temperature or between the temperature of the inner tube 12 or the boat 25 during loading of the substrate 1, which is at the lowest temperature, and the processing temperature, and compared with each other. It is known that a sintered body such as silicon carbide differs in coefficient of linear expansion depending on a sintering condition and obtains the coefficient of linear expansion of 3.1 to 4.4×10⁻⁶/K. For example, it is known that a sintered body with the coefficient of linear expansion of 3.9×10⁻⁶/K, which is substantially equal to that of Si, is obtained in a discharge plasma sintering method. In the discharge plasma sintering method, sintering is performed by causing a large pulsed current to flow while applying a pressure to nano-sized SiC ultrafine powder, and no sintering auxiliary agent is used. Further, large-scale molding entails technical difficulties. Further, the coefficient of linear expansion of the sintered body may be changed by selection of a known auxiliary agent (binder) or additives such as ZrO₂, Al₂O₃, SiO₂, TiO₂, TiC, WC, B₄C, MoSi₂, Si₃N₄, AlN, TiN, BN, TiB₂, ZrB₂, and LaB₆ by using silicon carbide as base material. The inner tube 12, the boat 25, and the process gas nozzle 21 in this example may be made of the sintered body with the coefficient of linear expansion substantially equal to that of Si, which is obtained by such a method.

By suppressing peeling-off of the deposited film accumulated on the inner surface of the inner tube 12, generation of particles may be prevented. Therefore, a frequency of cleaning the inner tube 12 may be reduced, and downtime is shortened, such that an operation rate of the substrate processing apparatus 10 may be improved.

For example, for quartz inner tubes in the related art, wet or dry cleaning of the inner tube 12 is recommended every 10 μm in cumulative film thickness. In a case of depositing a film with the film thickness of 2 μm in one process, cleaning is performed when the film formation is performed five times. Meanwhile, in the inner tube 12 made of material with the coefficient of linear expansion of ±8% or less with respect to the coefficient of linear expansion of deposits deposited on the surface of the substrate, it is possible to form a film without generating particles up to an accumulated film thickness of about 100 μm under an ideal condition. In a case where the coefficient of linear expansion exceeds ±8%, an allowable cumulative film thickness is significantly lower than 100 μm, and long-term maintenance-free operation may not be achieved.

Further, in the substrate processing apparatus 10 of this example, the inner tube may be inserted through the opening of the manifold, and the inserted inner tube may be easily attached to or detached from the inward flange of the manifold by a mounter. That is, it is possible to separate the inner tube without separating the outer tube. Therefore, the inner tube may be exchanged easily in a short time to perform the cleaning, thereby improving the operation rate of the substrate processing apparatus.

### [Other Embodiments]

The embodiments of the present disclosure are described above, but the present disclosure is not limited to the above-described embodiments and may, of course, be implemented in various modifications other than the above-described embodiments without departing from the gist of the present disclosure.

Further, the present disclosure is not limited to the above-described embodiments and various modifications may be made without departing from the gist of the present disclosure.

In the above-described embodiments, the screw holes 41 are formed in the seal flange 36 into which the vented set screws 43 or the set screws 44 is screwed, and the through-holes 42 are formed in the inward flange 17. However, the through-holes 42 may be formed in the seal flange 36, and the screw holes 41 may be formed in the inward flange 17.

In the above-described embodiments, the case of forming the polycrystalline silicon film is described, but the substrate processing apparatus 10 is not limited thereto and may also be applied to a case of forming a polycrystalline silicon germanium film. For example, a process condition when forming the polycrystalline silicon germanium film are as follows.

The precursor gas (flow rate is shown in parentheses) is, for example, SiH₄ (0.5 to 3 L/min), 10% diluted GeH₄ (3 L/min or less), 0.1% diluted BC13 (0.02 L/min or less). The pretreatment gas is, for example, H₂ (0.1 to 10 L/min). A pressure of the pretreatment gas is, for example, 0.1 to 100 Pa. For example, a pretreatment temperature is 700 to 1000 degree C., and a deposition temperature is 450 to 700 degree C.

Since the coefficient of linear expansion (4.2×10⁻⁶/K) of polycrystalline silicon germanium adhering to the inner surface of the inner tube 12 is almost the same as the coefficient of linear expansion (4.2×10⁻⁶/K) of silicon carbide (SiC) forming the inner tube 12, even when the temperature of the inner tube 12 and the temperature of the epitaxial silicon germanium adhering to the inner surface of the inner tube 12 change, it is difficult to peel off epitaxial silicon germanium adhering to the inner surface of the inner tube 12 from the inner tube 12.

The substrate processing apparatus in the present disclosure is not limited to the vertical CVD film-forming apparatus and may be applied to general film-forming apparatuses in which the temperature of the inner wall of the process chamber may change.

In the above-described embodiments, the inner tube 12 is made of silicon carbide (SiC), and the film deposited on the inner tube 12 is polycrystalline silicon or polycrystalline silicon germanium. However, as long as the coefficient of linear expansion of the material forming the inner tube 12 and the coefficient of linear expansion of the material of the film deposited on the inner tube 12 are close to each other, the material of the inner tube 12 and the material of the film deposited on the inner tube 12 are not limited to those of the above-described embodiments.

In the above-described embodiments, the number of vented set screws 43 as the conductance changer is regulated in advance, and when the substrate 1 is processed, the precursor gas 50 does not flow into the annular space 18 and the amount of used nitrogen gas supplied to the annular space 18 is controlled. However, the present disclosure is not limited thereto, and any structure that allows the conductance to be changed may be used. For example, a gas supply amount of each of the gas supplier configured to supply the process gas and the gas supplier configured to supply the nitrogen gas may be regulated to appropriately maintain the differential pressure between the process chamber 13 and the annular space 18. That is, the pressure difference caused by the purge gas flowing through the vent hole 43a may be directly controlled by the flow rate of the purge gas. Further, when performing a film formation in which the pressure of the process chamber 13 cyclically fluctuates due to repeated supply and stop of the precursor gas during processing, the flow rate controller 54 may be changed to a pressure controller and the pressure of the purge gas supplied by the pressure controller may be feedforward-controlled in conjunction with a target pressure pattern of the process chamber 13.

For example, the first pressure gauge 48 may detect the internal pressure of the process chamber 13 during processing of the substrate 1, and the second pressure gauge 52 may also detect the internal pressure of the annular space 18 during processing of the substrate 1. For example, the first pressure gauge 48 and the second pressure gauge 52 may be used in a case where the pressures are detected by the first pressure gauge 48 and the second pressure gauge 52 respectively during processing of the substrate 1, and an operation status of an apparatus is monitored and recorded or the apparatus is stopped when an abnormality is found in the apparatus, such as when the pressure is not within a prescribed range.

Hereinafter, some aspects of the present disclosure will be additionally described as supplementary notes.

### (Supplementary Note 1)

A substrate processing apparatus including:
a cylindrical outer tube with an upper end closed and a lower end opened;
an inner tube that is installed inside the outer tube, formed in a cylindrical shape with an upper end closed and a lower end opened, and configured such that a substrate is capable of being processed in a process chamber formed in the inner tube;
a manifold that is installed below the outer tube and the inner tube, in fluid communication with an internal space of the inner tube, and formed in a cylindrical shape with an exhaust space isolated from an annular space between the inner tube and the outer tube;
a process gas nozzle configured to supply a process gas that processes the substrate to an inside of the inner tube;
a purge gas nozzle configured to supply a purge gas to the annular space; and
a conductance changer that is installed at a partition wall between the annular space and the exhaust space, configured such that a gas is capable of passing between the annular space and the exhaust space, and configured to be capable of changing the passage conductance of the gas.

### (Supplementary Note 2)

The substrate processing apparatus of Supplementary Note 1, wherein a mounter is installed at the lower end of the inner tube and configured such that the inner tube is capable of being inserted through an opening of the manifold formed in the cylindrical shape, and the mounter is capable of being attached to or detached from an inward flange formed in an annular shape at an inner periphery of the manifold.

### (Supplementary Note 3)

The substrate processing apparatus of Supplementary Note 1 or 2, further including:
a first pressure gauge configured to detect a pressure of the internal space; and
a second pressure gauge configured to detect a pressure of the annular space.

### (Supplementary Note 4)

The substrate processing apparatus of any one of Supplementary Notes 1 to 3, wherein the inner tube is made of material with a coefficient of linear expansion being different with a difference of ±8% or less from a coefficient of linear expansion of a deposit deposited on an inner surface of the inner tube when the substrate is processed with the process gas.

### (Supplementary Note 5)

The substrate processing apparatus of any one of Supplementary Notes 1 to 4, wherein the inner tube is made of material with a coefficient of linear expansion that is substantially equal to a coefficient of linear expansion of a deposit deposited on an inner surface of the inner tube when the substrate is processed with the process gas.

### (Supplementary Note 6)

The substrate processing apparatus of Supplementary Note 4, wherein the deposit is silicon, and the inner tube is a sintered body containing silicon carbide as a main precursor.

### (Supplementary Note 7)

The substrate processing apparatus of any one of Supplementary Notes 1 to 4, wherein the conductance changer includes a plurality of screw holes formed to penetrate the partition wall, and at least one screw is configured to be screwed into any one of the plurality of screw holes.

### (Supplementary Note 8)

The substrate processing apparatus of Supplementary Note 2, wherein the manifold includes an upper flange that is installed at one end of a cylinder of the manifold and connected to the outer tube via a first seal material, a lower flange that is installed at the other end of the cylinder and connected to a housing supporting the outer tube via a second seal material, and the inward flange, which is installed at an inner periphery of the cylinder and configured to support the inner tube, and
wherein the conductance changer is installed at the inward flange or the mounter.

### (Supplementary Note 9)

The substrate processing apparatus of any one of Supplementary Notes 1 to 4, wherein the exhaust space of the manifold is in direct communication with the internal space of the inner tube without passing through the annular space, and
wherein an exhaust port configured to discharge a gas inside the inner tube is installed at the manifold.

### (Supplementary Note 10)

The substrate processing apparatus of Supplementary Note 2, wherein a film with a thickness of 2 μm or more is deposited on the substrate, which is accommodated inside the inner tube.

### (Supplementary Note 11)

A method of processing a substrate by using the substrate processing apparatus of Supplementary Note 1, including:
processing the substrate by supplying the process gas to the inner tube in which the substrate is placed, discharging the process gas supplied to the inner tube to an outside of the manifold via the exhaust space by supplying the purge gas to the annular space, and discharging the purge gas in the annular space to the outside of the manifold via the conductance changer and the exhaust space; and
after completion of the act of processing the substrate, discharging the process gas in the internal space to the outside of the manifold via the exhaust space by supplying the purge gas from the process gas nozzle to the internal space and supplying the purge gas from the purge gas nozzle to the annular space.

### (Supplementary Note 12)

A program that causes, by a computer, the substrate processing apparatus of Supplementary Note 1 to process the substrate by performing a process including:
processing the substrate by supplying the process gas to the inner tube in which the substrate is placed, discharging the process gas supplied to the inner tube to an outside of the manifold via the exhaust space by supplying the purge gas to the annular space, and discharging the purge gas in the annular space to the outside of the manifold via the conductance changer and the exhaust space; and
after completion of the substrate processing step, discharging the process gas in the internal space to the outside of the manifold via the exhaust space by supplying the purge gas from the process gas nozzle to the internal space and supplying the purge gas from the purge gas nozzle to the annular space.

According to the substrate processing apparatus and substrate processing method of the present disclosure in some embodiments, it is possible to suppress formation of a reaction product film on an inner surface of an outer tube.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a cylindrical outer tube with an upper end closed and a lower end opened;
an inner tube that is installed inside the outer tube, formed in a cylindrical shape with an upper end closed and a lower end opened, and configured such that a substrate is capable of being processed in a process chamber formed in the inner tube;
a manifold that is installed below the outer tube and the inner tube, in fluid communication with an internal space of the inner tube, and formed in a cylindrical shape with an exhaust space isolated from an annular space between the inner tube and the outer tube;
a process gas nozzle configured to supply a process gas that processes the substrate to an inside of the inner tube;
a purge gas nozzle configured to supply a purge gas to the annular space; and
a conductance changer that is installed at a partition wall between the annular space and the exhaust space, configured such that a gas is capable of passing between the annular space and the exhaust space, and configured to be capable of changing a passage conductance of the gas.

2. The substrate processing apparatus of claim 1, wherein a mounter is installed at the lower end of the inner tube and configured such that the inner tube is capable of being inserted through an opening of the manifold formed in the cylindrical shape, and the mounter is capable of being attached to or detached from an inward flange formed in an annular shape at an inner periphery of the manifold.

3. The substrate processing apparatus of claim 1, further comprising:
a first pressure gauge configured to detect a pressure of the internal space; and
a second pressure gauge configured to detect a pressure of the annular space.

4. The substrate processing apparatus of claim 1, wherein the inner tube is made of material with a coefficient of linear expansion being different with a difference of ±8% or less from a coefficient of linear expansion of a deposit deposited on an inner surface of the inner tube when the substrate is processed with the process gas.

5. The substrate processing apparatus of claim 1, wherein the inner tube is made of material with a coefficient of linear expansion that is substantially equal to a coefficient of linear expansion of a deposit deposited on an inner surface of the inner tube when the substrate is processed with the process gas.

6. The substrate processing apparatus of claim 4, wherein the deposit is silicon, and the inner tube is a sintered body containing silicon carbide as a main precursor.

7. The substrate processing apparatus of claim 1, wherein the conductance changer includes at least one screw hole formed to penetrate the partition wall and one or more screws configured to be screwed into the at least one screw hole.

8. The substrate processing apparatus of claim 2, wherein the inward flange and the mounter constitute the partition wall.

9. The substrate processing apparatus of claim 8, wherein the conductance changer includes a screw hole, which is formed in one of the inward flange and the mounter, and a through-hole formed in the other of the inward flange and the mounter such that the through-hole faces the screw hole.

10. The substrate processing apparatus of claim 7, wherein the at least one screw hole of the conductance changer includes a plurality of screw holes, and the one or more screws are screwed into any one of the plurality of screw holes.

11. The substrate processing apparatus of claim 7, wherein each of the one or more screws is formed with a vent hole through which a gas is capable of passing along an axial center of each of the one or more screws.

12. The substrate processing apparatus of claim 10, wherein a vented screw with a vent hole through which a gas is capable of passing along an axial center of the vented screw or one of the one or more screws without the vent hole is screwed into each of the plurality of screw holes.

13. The substrate processing apparatus of claim 1, further comprising: a pressure controller configured to be capable of controlling a pressure of the purge gas which is supplied to the purge gas nozzle, in cooperation with a target pressure pattern of the process chamber.

14. The substrate processing apparatus of claim 2, wherein the mounter includes:
a ring-shaped inner tube support installed to be interposed between the inward flange and the lower end of the inner tube;
a ring-shaped inner tube fitting ring installed at the opposite side of the inner tube support with a flange of the inner tube interposed therebetween;
a plurality of first fixing screws configured to connect the inner tube fitting ring and the inner tube support;
a ring-shaped seal flange installed at the opposite side of the inner tube support with the inward flange interposed therebetween; and
a plurality of second fixing screws configured to connect the seal flange and the inner tube support,
wherein the inner tube support is formed such that a plurality of protrusions protruding outward in a radial direction of the inner tube support are formed at intervals in a circumferential direction of the inner tube support at an outer periphery of the inner tube support, and
wherein the inward flange includes a plurality of notches through which the plurality of protrusions pass.

15. The substrate processing apparatus of claim 2, wherein the manifold includes an upper flange that is installed at one end of a cylinder of the manifold and connected to the outer tube via a first seal material, a lower flange that is installed at the other end of the cylinder and connected to a housing supporting the outer tube via a second seal material, and the inward flange, which is installed at an inner periphery of the cylinder and configured to support the inner tube, and
wherein the conductance changer is installed at the inward flange or the mounter.

16. The substrate processing apparatus of claim 1, wherein the exhaust space of the manifold is in direct communication with the internal space of the inner tube without passing through the annular space, and
wherein an exhaust port configured to discharge a gas inside the inner tube is installed at the manifold.

17. The substrate processing apparatus of claim 2, wherein a film with a thickness of 2 μm or more is deposited on the substrate, which is accommodated inside the inner tube.

18. A method of processing a substrate by using the substrate processing apparatus of claim 1, comprising:
processing the substrate by supplying the process gas to the inner tube in which the substrate is placed, discharging the process gas supplied to the inner tube to an outside of the manifold via the exhaust space by supplying the purge gas to the annular space, and discharging the purge gas in the annular space to the outside of the manifold via the conductance changer and the exhaust space; and
after completion of the act of processing the substrate, discharging the process gas in the internal space to the outside of the manifold via the exhaust space by supplying the purge gas from the process gas nozzle to the internal space and supplying the purge gas from the purge gas nozzle to the annular space.

19. A method of manufacturing a semiconductor device comprising the method of claim 18.

20. A non-transitory computer-readable recording medium storing a program that causes, by a computer, the substrate processing apparatus of claim 1 to process the substrate by performing a process comprising:
processing the substrate by supplying the process gas to the inner tube in which the substrate is placed, discharging the process gas supplied to the inner tube to an outside of the manifold via the exhaust space by supplying the purge gas to the annular space, and discharging the purge gas in the annular space to the outside of the manifold via the conductance changer and the exhaust space; and
after completion of the act of processing the substrate, discharging the process gas in the internal space to the outside of the manifold via the exhaust space by supplying the purge gas from the process gas nozzle to the internal space and supplying the purge gas from the purge gas nozzle to the annular space.
